(19) United States
(12) Patent Application Publication
(10) Pub. No.: US 2026/0271540 A1
(43) Pub. Date: Sep. 10, 2026

(54) DISPLAY APPARATUS AND ELECTRONIC DEVICE

(71) Applicant: Samsung Display Co., Ltd., Yongin-si (KR)

(72) Inventor: Hyuneok Shin, Yongin-si (KR)

(21) Appl. No.: 19/532,355

(22) Filed: Feb. 6, 2026

(30) Foreign Application Priority Data
Mar. 6, 2025 (KR) 10-2025-0029210

(51) Int. Cl. H10K 59/122; H10K 59/80

(52) U.S. Cl. CPC H10K 59/122; H10K 59/878; H10K 59/8792

(57) ABSTRACT

Embodiments include a display apparatus and an electronic device including the display apparatus. The display apparatus includes a substrate, a pixel electrode disposed on the substrate and including an emission area, a pixel-defining layer disposed on the pixel electrode and defining therein a pixel opening exposing the emission area of the pixel electrode, a reflective layer disposed on the pixel-defining layer and defining therein a reflective opening overlapping the pixel opening in a plan view and exposing the emission area of the pixel electrode, and an intermediate layer and an opposite electrode, which are disposed on the reflective layer and cover the emission area of the pixel electrode in the pixel opening and the reflective opening, where the reflective layer includes a light-absorbing layer disposed on the pixel-defining layer and a refractive layer disposed on the light-absorbing layer and being non-metallic.

This application claims priority to Korean Patent Application No. 10-2025-0029210, filed on Mar. 6, 2025, and all the benefits accruing therefrom under 35 U.S.C. §119, the content of which in its entirety is herein incorporated by reference.

### BACKGROUND

### 1. Field

One or more embodiments relate to an apparatus, and more particularly, to a display apparatus and an electronic device.

### 2. Description of the Related Art

Electronic devices have been widely used recently. Electronic devices are used in various forms such as portable electronic devices and stationary electronic devices, and such electronic devices include a display apparatus providing visual information such as images or videos to users to support various functions.

The display apparatus emits light from an emission layer to display an image, and the emitted light passes through various components of the display apparatus to reach the outside of the display apparatus. However, some of the light emitted from the emission layer may be trapped inside the display apparatus without reaching the outside of the display apparatus, which may deteriorate the light extraction efficiency of the display apparatus.

The above-mentioned background art is technical information that the inventor possessed for derivation of the disclosure or acquired in the process of derivation of the disclosure, and cannot necessarily be said to be known technology disclosed to the general public prior to the filing of the disclosure.

### SUMMARY

One or more embodiments include a display apparatus and an electronic device, in which light extraction efficiency may be improved.

However, this is merely an example, and the scope of the disclosure is not limited thereto.

Additional aspects will be set forth in part in the description which follows and, in part, will be apparent from the description, or may be learned by practice of the presented embodiments of the disclosure.

According to one or more embodiments, a display apparatus includes a substrate, a pixel electrode disposed on the substrate and including an emission area, a pixel-defining layer disposed on the pixel electrode and defining therein a pixel opening exposing the emission area of the pixel electrode, a reflective layer disposed on the pixel-defining layer and defining therein a reflective opening overlapping the pixel opening in a plan view and exposing the emission area of the pixel electrode, and an intermediate layer and an opposite electrode, which are disposed on the reflective layer and cover the emission area of the pixel electrode in the pixel opening and the reflective opening, where the reflective layer includes a light-absorbing layer disposed on the pixel defining layer and a refractive layer disposed on the upper portion of the light-absorbing layer.

In an embodiment, the refractive layer may have a refractive index in a range of 4.0 to 5.0.

In an embodiment, the refractive layer may include amorphous silicon (a-Si).

In an embodiment, the amorphous silicon may be hydrogenated amorphous silicon (a-Si:H).

In an embodiment, the light-absorbing layer may include a mixture of a molybdenum oxide and a transition metal oxide.

In an embodiment, the reflective layer may further define therein a disconnection groove surrounding the reflective opening and spaced apart from a perimeter of the reflective opening in a radial direction in the plan view.

In an embodiment, the disconnection groove may be provided as a closed loop surrounding the reflective opening in the plan view.

In an embodiment, the disconnection groove may include a first groove and a second groove, wherein the first groove may surround the reflective opening, and the second groove may surround the first groove and be spaced apart from the first groove.

In an embodiment, the refractive layer may include a first tip portion protruding toward the disconnection groove in the plan view.

In an embodiment, the first tip portion may protrude beyond an edge of the light-absorbing layer.

In an embodiment, the intermediate layer may include a common layer and an emission layer disposed on the common layer, and the common layer may be disconnected by the first tip portion.

In an embodiment, the refractive layer may include a second tip portion protruding toward the reflective opening.

In an embodiment, the second tip portion may protrude beyond an edge of the light-absorbing layer.

In an embodiment, the intermediate layer may include a common layer and an emission layer disposed on the common layer, and the common layer may be disconnected by the second tip portion.

According to one or more embodiments, a display apparatus includes a substrate, a first pixel electrode including a first emission area and a second pixel electrode including a second emission area, the first pixel electrode and the second pixel electrode being disposed on the substrate, a pixel defining layer disposed between and partially on the first pixel electrode and the second pixel electrode and exposing the first emission area and the second emission area, and a reflective layer disposed on the pixel-defining layer, wherein the reflective layer may include a light-absorbing layer disposed on the pixel-defining layer and a refractive layer disposed on the light-absorbing layer.

In an embodiment, the pixel-defining layer may include an inclined surface, which is convex, and the reflective layer may be inclined along the inclined surface.

In an embodiment, the refractive layer may have a refractive index in a range of 4.0 to 5.0.

In an embodiment, the light-absorbing layer may include a mixture of a molybdenum oxide and a transition metal oxide.

In an embodiment, the reflective layer may further define therein a disconnection groove between the first pixel electrode and the second pixel electrode, and the disconnection groove may be disposed on the inclined surface.

In an embodiment, the refractive layer may include a first tip portion protruding toward the disconnection groove.

According to one or more embodiments, an electronic device includes a display apparatus and a housing accommodating the display apparatus, the display apparatus includes a substrate, a pixel electrode disposed on the substrate and including an emission area, a pixel-defining layer disposed on the pixel electrode and defining therein a pixel opening exposing the emission area of the pixel electrode, a reflective layer disposed on the pixel-defining layer and defining therein a reflective opening overlapping the pixel opening in a plan view and exposing the emission area of the pixel electrode, and an intermediate layer and an opposite electrode, which are disposed on the reflective layer and cover the emission area of the pixel electrode in the pixel opening and the reflective opening, where the reflective layer includes a light-absorbing layer disposed on the pixel-defining layer and a refractive layer disposed on the light-absorbing layer.

Other aspects, features and advantages other than those described above will become apparent from the following detailed description, claims and drawings for practicing the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1A is a schematic perspective view of an electronic device according to an embodiment;

FIG. 1B is a schematic perspective view of a display apparatus according to an embodiment;

FIG. 2 shows a light-emitting diode provided in one of pixels of a display apparatus according to an embodiment, and a pixel circuit connected to the light-emitting diode;

FIG. 3 is a schematic cross-sectional view of a display apparatus according to an embodiment, taken along line III-III' of FIG. 1B;

FIGS. 4 and 5 are schematic enlarged cross-sectional views of an area IV of the display apparatus of FIG. 3, according to an embodiment;

FIG. 6 is a schematic enlarged cross-sectional view of an area VI of the display apparatus of FIG. 4, according to an embodiment; and

FIGS. 7 to 11 are diagrams schematically showing a method of manufacturing a display apparatus, according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term "and/or" includes any and all combinations of one or more of the associated listed items. Throughout the disclosure, the expression "at least one of a, b or c" indicates only a, only b, only c, both a and b, both a and c, both b and c, all of a, b, and c, or variations thereof.

Various modifications may be applied to the present embodiments, and particular embodiments will be illustrated in the drawings and described in the detailed description section. The effect and features of the present embodiments, and a method to achieve the same, will be clearer referring to the detailed descriptions below with the drawings. However, the present embodiments may be implemented in various forms, not by being limited to the embodiments presented below.

Hereinafter, embodiments will be described, in detail, with reference to the accompanying drawings, and in the description with reference to the drawings, the same or corresponding components are indicated by the same reference numerals and redundant descriptions thereof are omitted.

In the following embodiments, it will be understood that although the terms "first," "second," etc. may be used herein to describe various components, these components should not be limited by these terms. These terms are only used to distinguish one component from another.

In the following embodiments, the expression of singularity in the specification includes the expression of plurality unless clearly specified otherwise in context.

In the following embodiments, it will be further understood that the terms "includes," "has," "including," and/or "having" used herein specify the presence of stated features or components, but do not preclude the presence or addition of one or more other features or components.

In the following embodiments, it will be understood that when a layer, region, or component is referred to as being "formed on" another layer, region, or component, it can be directly or indirectly formed on the other layer, region, or component. That is, for example, intervening layers, regions, or components may be present.

In the following embodiments, when layers, regions, or components are connected to each other, the layers, the regions, or the components may be directly connected to each other, or another layer, another region, or another component may be disposed between the layers, the regions, or the components and thus the layers, the regions, or the components may be indirectly connected to each other. In addition, when layers, regions, or components are electrically connected to each other, the layers, the regions, or the components may be directly electrically connected to each other, or another layer, another region, or another component may be disposed between the layers, the regions, or the components and thus the layers, the regions, or the components may be indirectly electrically connected to each other.

Sizes of elements in the drawings may be exaggerated or reduced for convenience of explanation. For example, since sizes and thicknesses of components in the drawings are arbitrarily illustrated for convenience of explanation, the following embodiments are not limited thereto.

In the following embodiments, the expression "A and/or B" may include A, B, or A and B. Furthermore, the expression "at least one of A and B" may include A, B, or A and B.

As used herein, when a wiring is referred to as "extending in a first direction or a second direction," it means that the wiring not only extends in a straight-line form but also extends in a zigzag or in a curve in the first direction or the second direction.

As used herein, "in a plan view" means that an objective portion is viewed from above (in other words, a view in a thickness direction (i.e., z-axis direction) of the display apparatus 2). In addition, "in a cross-sectional view" means that a cross-section of an objective portion taken vertically is viewed from a lateral side. In the following embodiments, "overlapping" of a first component and a second component means that the first component is located above or below the second component.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

When a certain embodiment may be implemented differently, a specific process order may be performed differently from the described order. For example, two consecutively described processes may be performed substantially at the same time or performed in an order opposite to the described order.

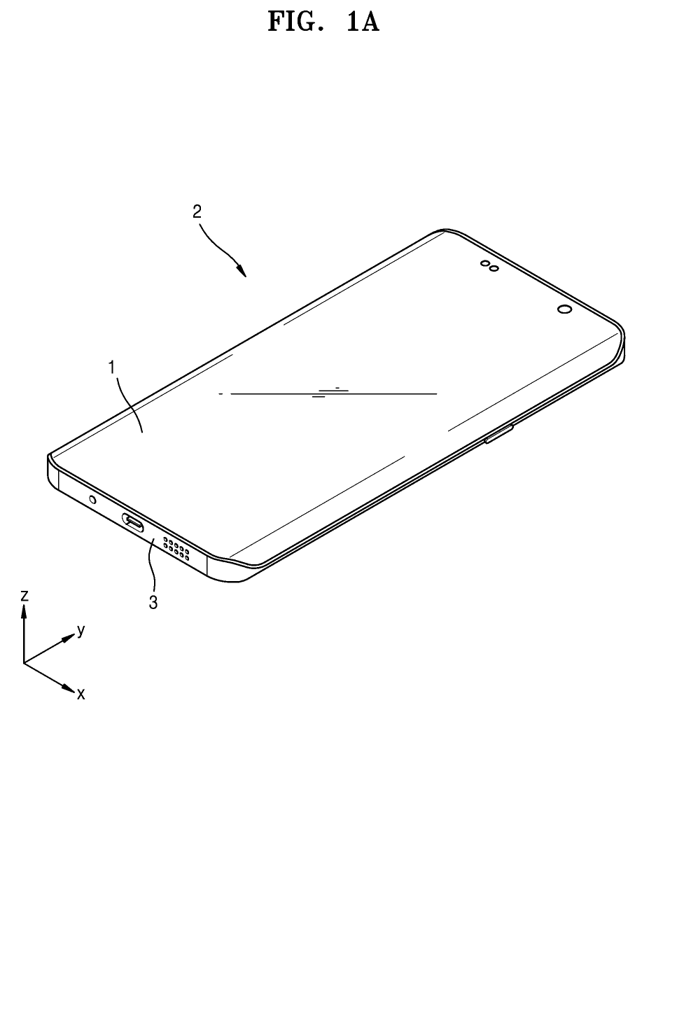

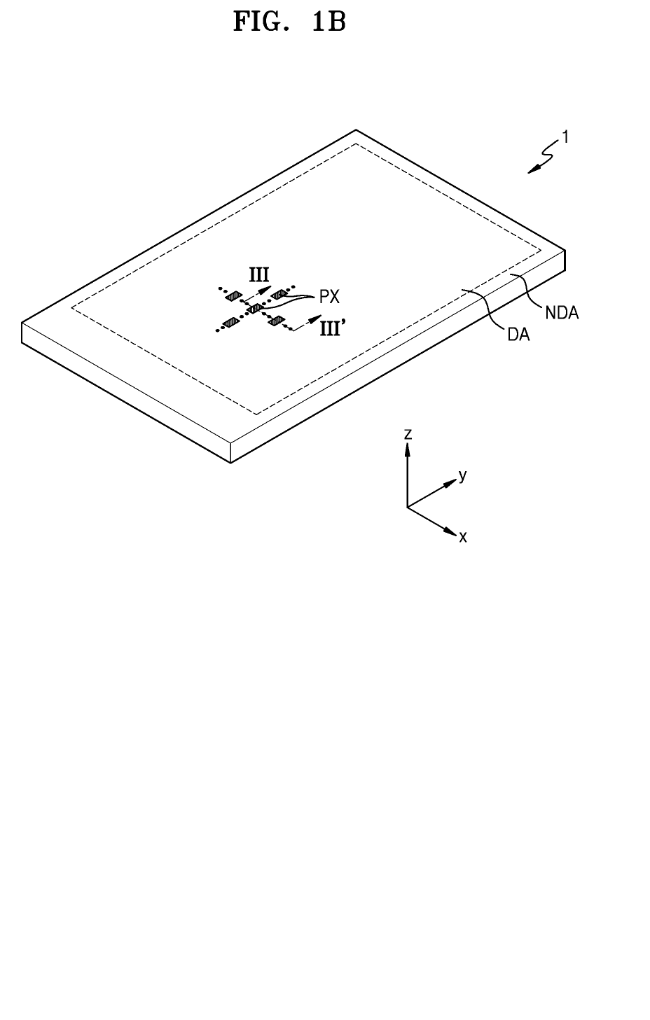

FIG. 1A is a schematic perspective view of an electronic device according to an embodiment. FIG. 1B is a schematic perspective view of a display apparatus according to an embodiment.

Referring to FIGS. 1A and 1B, a display apparatus 1 is a device for displaying moving images or still images, and may display a screen or perform input and output of data in an electronic device 2. In FIG. 1A, the display apparatus 1 is shown as being used in a mobile phone as an embodiment, but it is not necessarily limited thereto, and the display apparatus 1 may be used as a display screen of not only portable electronic devices such as mobile phones, smartphones, tablet PCs, mobile communication terminals, electronic organizers, electronic books, portable multimedia players (PMPs), navigation devices, and Ultra Mobile PCs (UMPCs), but also various electronic devices such as televisions, laptop computers, monitors, billboards, and internet of things (IOT) devices. In addition, the display apparatus 1 according to an embodiment may be used in electronic devices such as wearable devices such as smart watches, watch phones, glasses-type displays, and head mounted displays (HMDs). In addition, the display apparatus 1 according to an embodiment may be used as a display of various electronic devices, for example, an instrument panel of a vehicle, a center information display (CID) disposed in a center fascia or dashboard of a vehicle, a room mirror display replacing a side mirror of a vehicle, and a display disposed on a rear surface of a front seat as entertainment for a back seat of a vehicle.

In an embodiment, the display apparatus 1 may be accommodated in a housing 3 of the electronic device 2. The housing 3 may be a cover that protects internal components such as the display apparatus 1 and may form the exterior of the electronic device 2. In addition, the display apparatus 1 may be connected to an electronic module of the electronic device 2 and may be driven in the electronic device 2. Hereinafter, the description will focus on the display apparatus 1.

Referring to FIG. 1B, the display apparatus 1 may include a display area DA and a peripheral area NDA outside the display area DA. The display apparatus 1 may provide an image through an array of a plurality of pixels PX two-dimensionally disposed in the display area DA.

Each pixel PX of the display apparatus 1 is a region that may emit light of a certain color, and the display apparatus 1 may provide an image by using light emitted from the pixels PX. For example, each pixel PX may emit red light, green light, blue light, or white light.

Each of the pixels PX may emit light of a certain color by using a light-emitting diode, for example, an organic light-emitting diode. Each organic light-emitting diode may emit, for example, red light, green light, blue light, or white light. Each organic light-emitting diode may be connected to a pixel circuit including a thin-film transistor and a capacitor.

The peripheral area NDA is an area that does not provide an image and may entirely surround the display area DA. A driver or a main power line for providing electrical signals or power to the pixel circuits may be disposed in the peripheral area NDA. The peripheral area NDA may include a pad, which may be electrically connected to electronic elements or printed circuit boards.

The display area DA may have a polygonal shape including a rectangle, as shown in FIG. 1B. For example, the display area DA may have a rectangular shape with a horizontal length greater than a vertical length, a rectangular shape with a horizontal length less than a vertical length, or a square shape. Alternatively, the display area DA may have any one of various shapes such as an oval and a circular shape.

The display apparatus 1 may be included in electronic devices such as mobile phones, televisions, billboards, tablet PCs, laptop computers, smart watches, and smart bands worn on a wrist.

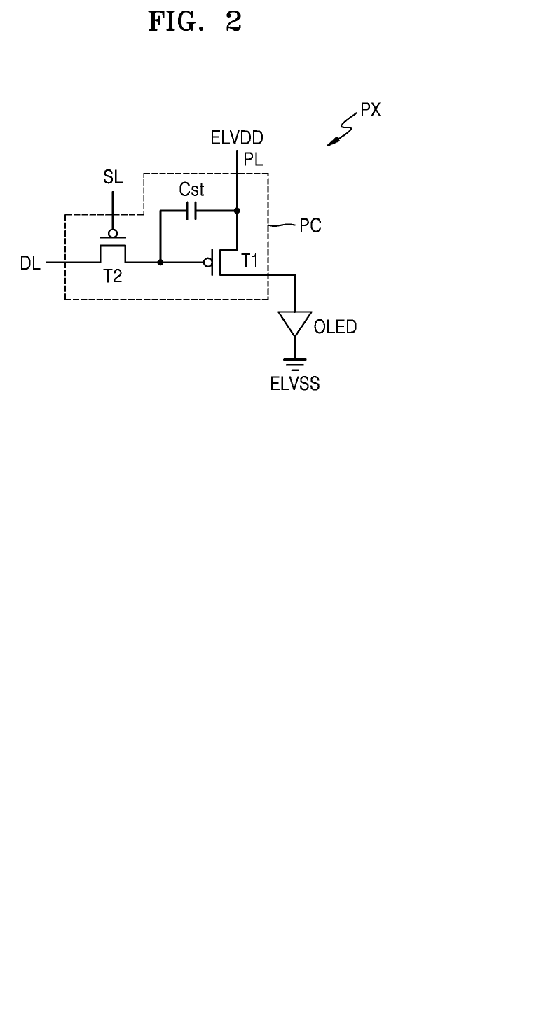

FIG. 2 shows a light-emitting diode provided in one of pixels of a display apparatus according to an embodiment, and a pixel circuit connected to the light-emitting diode.

Referring to FIG. 2, as a light-emitting diode, an organic light-emitting diode OLED is connected to a pixel circuit PC. The pixel circuit PC may include a first thin-film transistor T1, a second thin-film transistor T2, and a storage capacitor Cst.

The second thin-film transistor T2, as a switching thin-film transistor, is connected to a scan line SL and a data line DL, and may be configured to transfer a data voltage input from the data line DL to the first thin-film transistor T1 according to a switching voltage input from the scan line SL. The storage capacitor Cst is connected to the second thin-film transistor T2 and a driving voltage line PL, and may store a voltage corresponding to the difference between the voltage received from the second thin-film transistor T2 and a driving voltage ELVDD supplied to the driving voltage line PL.

The first thin-film transistor T1, as a driving thin-film transistor, is connected to the driving voltage line PL and the storage capacitor Cst, and may control a driving current flowing from the driving voltage line PL to the organic light-emitting diode OLED in correspondence with a value of the voltage stored in the storage capacitor Cst. The organic light-emitting diode OLED may emit light with a certain brightness by means of the driving current. A pixel electrode (for example, an anode) of the organic light-emitting diode OLED may be connected to the pixel circuit PC. An opposite electrode (for example, a cathode) of the organic light-emitting diode OLED may receive a common voltage ELVSS.

Although FIG. 2 describes that the pixel circuit PC includes two thin-film transistors and one storage capacitor, it is understood that the number of thin-film transistors or the number of storage capacitors may be variously changed according to the design of the pixel circuit PC in some embodiments.

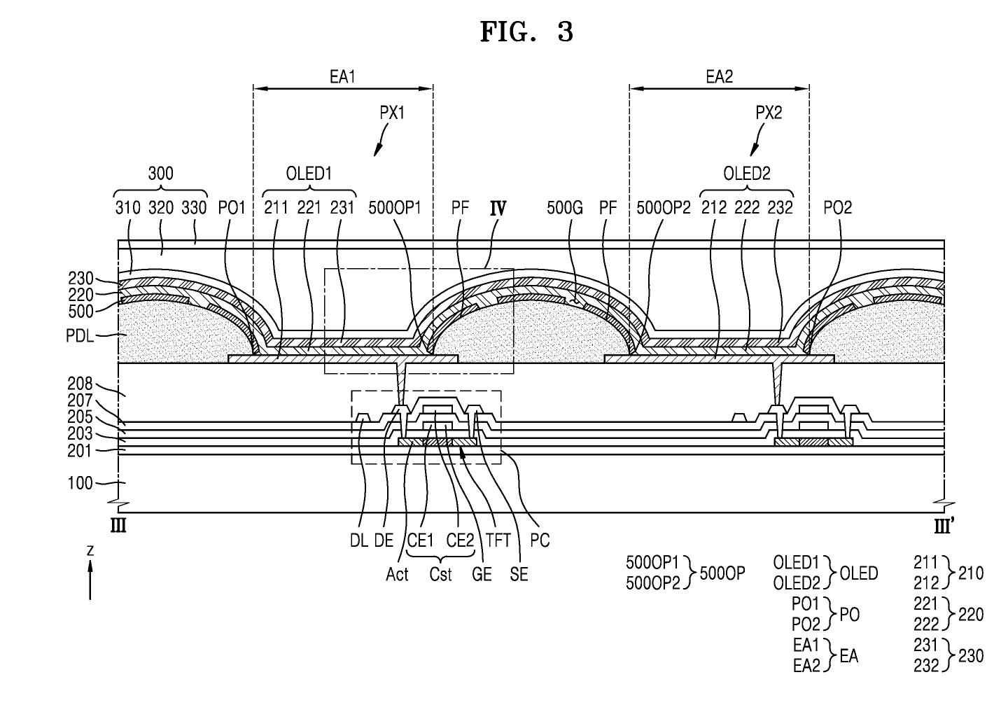

FIG. 3 is a schematic cross-sectional view of a display apparatus according to an embodiment, taken along line III-III' of FIG. 1B.

Referring to FIG. 3, the display apparatus 1 according to the present embodiment may include a substrate 100. The substrate 100 may include various materials having flexible or bendable characteristics. For example, the substrate 100 may include glass, metal, or polymer resin. In addition, the substrate 100 may include a polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 100 may have various modifications, for example, the substrate 100 may have a multi-layer structure including two layers each including the polymer resin and a barrier layer including an inorganic material (such as silicon oxide, silicon nitride, or silicon oxynitride) between the two layers.

On the substrate 100, the pixels PX each including a display element and the pixel circuit PC may be disposed. In FIG. 3, each of the pixels PX is illustrated as including the organic light-emitting diode OLED as the display element. For example, the organic light-emitting diode OLED may correspond to a first organic light-emitting diode OLED1 or a second organic light-emitting diode OLED2. That is, a first pixel PX1 may include the first organic light-emitting diode OLED1, and a second pixel PX2 may include the second organic light-emitting diode OLED2.

The pixel circuit PC may be disposed on the substrate 100. Because the structures of the pixel circuits PC of the pixels PX are the same, the description will focus on one pixel circuit PC. The pixel circuit PC includes a plurality of thin-film transistors TFT and the storage capacitor Cst. For convenience of illustration, one thin-film transistor TFT is illustrated in FIG. 3, and the thin-film transistor TFT may correspond to the first thin-film transistor T1 (see FIG. 2) as the driving thin-film transistor described above.

A buffer layer 201 including an inorganic material, such as silicon oxide, silicon nitride, and/or silicon oxynitride, may be disposed between the thin-film transistor TFT and the substrate 100. The buffer layer 201 may increase the smoothness of an upper surface of the substrate 100 or prevent or reduce impurities from the substrate 100 or the like from penetrating into a semiconductor layer Act of the thin-film transistor TFT.

As illustrated in FIG. 3, the thin-film transistor TFT may have the semiconductor layer Act including amorphous silicon, polycrystalline silicon, an organic semiconductor material, or an oxide semiconductor material. In addition, the thin-film transistor TFT may include a gate electrode GE, a source electrode SE, and/or a drain electrode DE. The gate electrode GE may include various conductive materials and may have various layered structures. For example, the gate electrode GE may include a molybdenum (Mo) layer and an aluminum (Al) layer. Alternatively, the gate electrode GE may include a titanium nitride (TiNx) layer, an aluminum (Al) layer, and/or a titanium (Ti) layer. Each of the source electrode SE and the drain electrode DE may also include various conductive materials and may have various layered structures. For example, each of the source electrode SE and the drain electrode DE may include a titanium (Ti) layer, an aluminum (Al) layer, and/or a copper (Cu) layer.

In order to secure insulation between the semiconductor layer Act and the gate electrode GE, a gate insulating layer 203 including an inorganic material such as silicon oxide, silicon nitride, and/or silicon oxynitride may be disposed between the semiconductor layer Act and the gate electrode GE. In FIG. 3, the gate insulating layer 203 is illustrated as having a shape corresponding to the entire surface of the substrate 100 and having a structure in which contact holes are formed in predetermined portions, but the disclosure is not necessarily limited thereto. For example, the gate insulating layer 203 may be patterned to have the same shape as the gate electrode GE.

In addition, a first interlayer insulating layer 205 including an inorganic material such as silicon oxide, silicon nitride, and/or silicon oxynitride may be disposed on the gate electrode GE. The first interlayer insulating layer 205 may have a single-layer or multi-layer structure including the aforementioned material. An insulating layer including the inorganic material may be formed through chemical vapor deposition (CVD) or atomic layer deposition (ALD). The same applies to embodiments to be described below and modifications thereof.

The storage capacitor Cst may include a first capacitor electrode CE1 and a second capacitor electrode CE2 that overlap each other with the first interlayer insulating layer 205 therebetween. The storage capacitor Cst may overlap the thin-film transistor TFT. In this regard, FIG. 3 illustrates that the gate electrode GE of the thin-film transistor TFT is the first capacitor electrode CE1 of the storage capacitor Cst. However, the disclosure is not necessarily limited thereto. For example, the storage capacitor Cst may not overlap the thin-film transistor TFT. The second capacitor electrode CE2 of the storage capacitor Cst may include a conductive material including molybdenum (Mo), aluminum (Al), copper (Cu), titanium (Ti), or the like, and may have a multi-layer or single-layer structure including the conductive material.

A second interlayer insulating layer 207 including an inorganic material such as silicon oxide, silicon nitride and/or silicon oxynitride may be disposed on the second capacitor electrode CE2 of the storage capacitor Cst. The second interlayer insulating layer 207 may have a single-layer or multi-layer structure including the aforementioned material.

The source electrode SE and the drain electrode DE may be disposed on the second interlayer insulating layer 207. The data line DL may be located on the same layer as the source electrode SE and the drain electrode DE and may include the same material as the source electrode SE and the drain electrode DE. The source electrode SE, the drain electrode DE, and the data line DL may each include a material having excellent conductivity. The source electrode SE and the drain electrode DE may each include a conductive material including molybdenum (Mo), aluminum (Al), copper (Cu), titanium (Ti), or the like and may have a multi-layer or single-layer structure including the conductive material. For example, the source electrode SE, the drain electrode DE, and the data line DL may each have a multi-layer structure of Ti/Al/Ti.

However, the disclosure is not necessarily limited thereto. For example, the thin-film transistor TFT may have only one of the source electrode SE and the drain electrode DE, or may have neither of them. For example, one thin-film transistor TFT may not have the drain electrode DE, another thin-film transistor TFT connected to one thin-film transistor TFT may not have the source electrode SE, and the semiconductor layers Act of these two thin-film transistors TFT may be connected to each other. This connection structure may exhibit the same effect as when one thin-film transistor TFT has the source electrode SE, another thin-film transistor TFT has the drain electrode DE, and the source electrode SE of the one thin-film transistor TFT is connected to the drain electrode DE of the other thin-film transistor TFT.

As illustrated in FIG. 3, a planarization layer 208 may cover the thin-film transistor TFT and the storage capacitor Cst. The planarization layer 208 may include an organic insulating material. For example, the planarization layer 208 may include a photoresist, benzocyclobutene (BCB), polyimide, hexamethyldisiloxane (HMDSO), polymethylmethacrylate (PMMA), polystyrene, a polymer derivative having a phenol group, an acrylic polymer, an imide polymer, an aryl ether polymer, an amide polymer, a fluorinated polymer, a p-xylene polymer, a vinyl alcohol polymer, or a mixture thereof. Although not shown in FIG. 3, a third interlayer insulating layer (not shown) may be further disposed under the planarization layer 208. The third interlayer insulating layer may include an inorganic insulating material such as silicon oxide, silicon nitride or silicon oxynitride.

On the planarization layer 208, the first organic light-emitting diode OLED1 and the second organic light-emitting diode OLED2 may be spaced apart from each other.

A plurality of pixel electrodes 210 may be disposed on the planarization layer 208. In an embodiment, the plurality of pixel electrodes 210 may include a first pixel electrode 211 included in the first pixel PX1 and a second pixel electrode 212 included in the second pixel PX2. The first pixel electrode 211 and the second pixel electrode 212 may be spaced apart from each other on the planarization layer 208. The first pixel electrode 211 and the second pixel electrode 212 may each include a light-transmitting conductive layer including a light-transmitting conductive oxide such as ITO, In₂O₃ or IZO, and a reflective layer including a metal such as aluminum (Al) or silver (Ag). For example, the first pixel electrode 211 and the second pixel electrode 212 may each have a three-layer structure of ITO/Ag/ITO.

The first pixel electrode 211 and the second pixel electrode 212 may be electrically connected to the thin-film transistor TFT by contact with one of the source electrode SE and the drain electrode DE, as illustrated in the drawings. Specifically, each of the first pixel electrode 211 and the second pixel electrode 212 may be in contact with one of the source electrode SE and the drain electrode DE through a contact hole formed in the planarization layer 208.

A pixel-defining layer PDL may be disposed on the planarization layer 208. The pixel-defining layer PDL defines an emission area EA by a pixel opening PO therein exposing at least a portion of the pixel electrode 210. The emission area EA is an area where light is emitted and may be an area corresponding to a central portion of the pixel electrode 210.

The pixel-defining layer PDL may define therein the pixel opening PO. The pixel opening PO may overlap the pixel electrode 210 to expose a portion of the pixel electrode 210 in a plan view. In an embodiment, the pixel opening PO may include a first pixel opening PO1 defined on the first pixel electrode 211 and a second pixel opening PO2 defined on the second pixel electrode 212. In an embodiment, the first pixel opening PO1 may define a first emission area EA1. The second pixel opening PO2 may define a second emission area EA2.

The pixel-defining layer PDL may increase the distance between an edge of the pixel electrode 210 and the opposite electrode 230 above the pixel electrode 210. As a result, arcing or the like may be prevented from occurring at the edge of the pixel electrode 210. The pixel-defining layer PDL may include an organic material such as polyimide or hexamethyldisiloxane (HMDSO).

As illustrated in the cross-sectional view shown in FIG. 3, in an embodiment, the pixel-defining layer PDL may be disposed between the first pixel electrode 211 and the second pixel electrode 212. In this case, the pixel-defining layer PDL may include an inclined surface PF, which is convex toward an upper direction. The inclined surface PF may be downwardly inclined toward each of the first pixel electrode 211 and the second pixel electrode 212. In this case, the cross-section of the pixel-defining layer PDL may have, for example, a semi-circular shape. Alternatively, the cross-section of the pixel-defining layer PDL may have, for example, a regular trapezoid shape.

A reflective layer 500 may be disposed on the pixel-defining layer PDL. The reflective layer 500 may cover the pixel-defining layer PDL. In an embodiment, the reflective layer 500 may define therein a reflective opening 500OP. The reflective opening 500OP may overlap the pixel opening PO to expose a portion of the pixel electrode 210 in a plan view. That is, the reflective opening 500OP may expose the emission area EA of the pixel electrode 210. For example, the reflective opening 500OP may include a first reflective opening 500OP1 defined on the first pixel electrode 211 and a second reflective opening 500OP2 defined on the second pixel electrode 212. The first reflective opening 500OP1 may overlap the first pixel opening PO1. The second reflective opening 500OP2 may overlap the second pixel opening PO2 in a plan view. The reflective layer 500 may reflect light emitted from an emission layer EML to be described below, to allow the light to exit the display apparatus 1. The reflective layer 500 may improve light extraction efficiency by changing a light path.

An intermediate layer 220 may be disposed on the reflective layer 500. In an embodiment, the intermediate layer 220 may overlap at least a portion of the reflective layer 500 and at least a portion of the pixel electrode 210 exposed by the reflective opening 500OP and the pixel opening PO. For example, the intermediate layer 220 may cover the reflective layer 500 and cover the pixel electrode 210 exposed by the reflective opening 500OP and the pixel opening PO. In an embodiment, the intermediate layer 220 may include a first intermediate layer 221, which is a portion overlapping the first pixel electrode 211, and a second intermediate layer 222, which is a portion overlapping the second pixel electrode 212. In an embodiment, the intermediate layer 220 may include a low-molecular-weight or high-molecular-weight material.

When the intermediate layer 220 includes a low-molecular-weight material, the intermediate layer 220 may have a structure in which a hole injection layer (HIL), a hole transport layer (HTL), an emission layer (EML), an electron transport layer (ETL), and an electron injection layer (EIL) are stacked in a single or composite structure, and may be formed by a vacuum deposition method.

When the intermediate layer 220 includes a high-molecular-weight material, the intermediate layer 220 may have a structure including the HTL and the EML. In this case, the HTL may include PEDOT, and the EML may include a polymer material such as polyphenylene vinylene (PPV) or polyfluorene. The intermediate layer 220 may be formed by screen printing, inkjet printing, laser induced thermal imaging (LITI), or the like.

An opposite electrode 230 may be disposed on the intermediate layer 220. The intermediate layer 220 may be disposed between the pixel electrode 210 and the opposite electrode 230. In addition, since the opposite electrode 230 is disposed on the intermediate layer 220, the opposite electrode 230 may overlap at least a portion of the reflective layer 500 and at least a portion of the pixel electrode 210 exposed by the reflective opening 500OP and the pixel opening PO. In an embodiment, the opposite electrode 230 may include a first opposite electrode 231, which is a portion overlapping the first pixel electrode 211, and a second opposite electrode 232, which is a portion overlapping the second pixel electrode 212.

The opposite electrode 230 may include a light-transmitting conductive layer including ITO, In₂O₃, or IZO, and may also include a semi-transmissive layer including a metal such as Al or Ag. For example, the opposite electrode 230 may include a semi-transmissive layer including magnesium (Mg) or Ag. Although not shown in the drawings, a capping layer (not shown) may be located on the opposite electrode 230. For example, the capping layer may include a single layer or multiple layers including a material selected from an organic material, an inorganic material, and a mixture thereof. In an embodiment, a LiF layer may be located on the capping layer. Meanwhile, the opposite electrode 230 may be deposited on the entire surface of the substrate 100.

An encapsulation layer 300 may be disposed on the opposite electrode 230. The encapsulation layer 300 may be disposed on the opposite electrode 230 to entirely cover the opposite electrode 230. The encapsulation layer 300 may include at least one inorganic encapsulation layer and at least one organic encapsulation layer. In an embodiment, the encapsulation layer 300 may include a first inorganic encapsulation layer 310, an organic encapsulation layer 320, and a second inorganic encapsulation layer 330. The first inorganic encapsulation layer 310 may be disposed on the opposite electrode 230 and may entirely cover the opposite electrode 230. The organic encapsulation layer 320 may be disposed on the first inorganic encapsulation layer 310 and may be a planarization layer that planarizes undulations and irregularities on the upper surface of the first inorganic encapsulation layer 310. The second inorganic encapsulation layer 330 may be disposed on the organic encapsulation layer 320 and may entirely cover the organic encapsulation layer 320. In other words, the organic encapsulation layer 320 may be disposed between the first inorganic encapsulation layer 310 and the second inorganic encapsulation layer 330.

The first inorganic encapsulation layer 310 and the second inorganic encapsulation layer 330 may include an inorganic insulating material such as silicon oxide (SiOₓ), silicon nitride (SiNₓ) or silicon oxynitride (SiON). The organic encapsulation layer 320 may include at least one organic insulating material selected from polyethylene terephthalate (PET), polyethylene naphthalate (PEN), polycarbonate (PC), polyamide (PI), polyethylene sulfonate (PES), polyoxymethylene (POM), polyarylate (PAR), and hexamethyldisiloxane (HMDSO). The disclosure is not necessarily limited to the aforementioned materials.

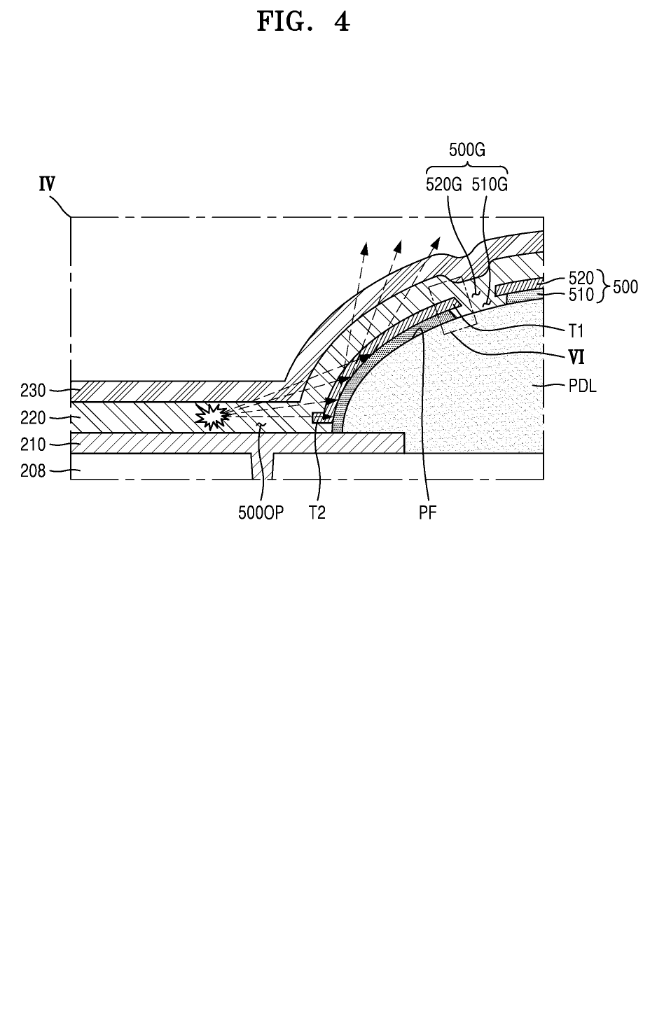

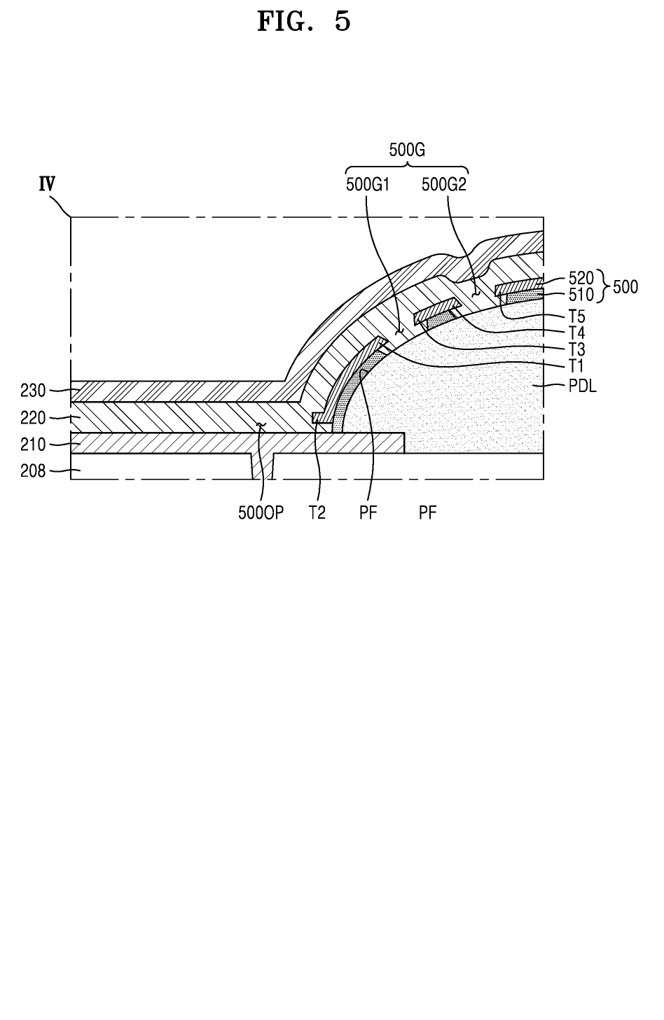

FIGS. 4 and 5 are schematic enlarged cross-sectional views of an area IV of the display apparatus of FIG. 3, according to an embodiment. In FIGS. 4 and 5, the encapsulation layer 300 is omitted for convenience of explanation.

Referring to FIG. 4 together with FIG. 3, in an embodiment, the reflective layer 500 may include a light-absorbing layer 510 and a refractive layer 520. The light-absorbing layer 510 may be disposed on the pixel-defining layer PDL, and the refractive layer 520 may be disposed on the light-absorbing layer 510.

In an embodiment, the light-absorbing layer 510 may absorb light so that light emitted from the emission layer of the intermediate layer 220 may not leak toward adjacent pixels. In an embodiment, the light-absorbing layer 510 may include a mixture of a molybdenum oxide and a transition metal oxide. For example, the light-absorbing layer 510 may be a mixture of a molybdenum oxide (MoOₓ) and a vanadium oxide (VOₓ). Alternatively, the light-absorbing layer 510 may be a mixture of a molybdenum oxide (MoOₓ) and a titanium oxide (TiOₓ). When only molybdenum oxide having excellent light absorption characteristics is used in the display apparatus 1, a lift-off phenomenon may occur due to its high solubility in water. Therefore, in the display apparatus 1, a transition metal oxide may be mixed with molybdenum oxide, which may control solubility in water and prevent the lift-off phenomenon. In addition, the light-absorbing layer 510 may more easily absorb light to prevent light leakage. In an embodiment, the transition metal oxide may be 0.5 weight percentages (wt%) to 10 wt%.

In an embodiment, the refractive layer 520 may reflect, that is, refract, light emitted from the emission layer of the intermediate layer 220, to allow more light to exit to the outside of the display apparatus 1. In an embodiment, the refractive layer 520 may include amorphous silicon (a-Si). For example, the refractive layer 520 may include hydrogenated amorphous silicon (a-Si:H). The amorphous silicon (a-Si), for example, hydrogenated amorphous silicon (a-Si:H), as described above, may have a high refractive index. In an embodiment, the refractive index of the refractive layer 520 may be 4.0 to 5.0, for example, 4.1. As such, the refractive layer 520 may include amorphous silicon to implement high refraction with a non-metallic material and increase light extraction efficiency. In addition, because a non-metallic material is used (i.e., metallic material is not included in the refractive layer 520), vertical leakage of a current may be prevented compared to when a metallic material is used.

Meanwhile, in an embodiment, the reflective layer 500 may define therein a disconnection groove 500G. The disconnection groove 500G may be a groove penetrating the reflective layer 500. Accordingly, the intermediate layer 220 disposed on the reflective layer 500 may be in contact with the pixel-defining layer PDL exposed by the disconnection groove 500G. In a plan view, the disconnection groove 500G may surround the reflective opening 500OP of the reflective layer 500. The disconnection groove 500G may surround the reflective opening 500OP and may be spaced apart from the perimeter of the reflective opening 500OP in a radial direction. In this case, the disconnection groove 500G may be provided as a closed loop surrounding the reflective opening 500OP. For example, the disconnection groove 500G may have a ring shape in a plan view.

In an embodiment, the disconnection groove 500G may be disposed on the inclined surface PF of the pixel-defining layer PDL. As described above, the pixel-defining layer PDL may include an inclined surface PF, which is convex. For example, the inclined surface PF may be downwardly inclined toward each of the first pixel electrode 211 and the second pixel electrode 212. The reflective layer 500 may be inclined along the inclined surface PF, and the disconnection groove 500G may be formed to expose a portion of the inclined surface PF. In addition, in an embodiment, the disconnection groove 500G may be disposed between the first pixel electrode 211 and the second pixel electrode 212.

Meanwhile, it will be understood that the disconnection groove 500G may be defined with respect to the light-absorbing layer 510 and the refractive layer 520. Specifically, the light-absorbing layer 510 may include a first sub-groove 510G, and the refractive layer 520 may include a second sub-groove 520G. The first sub-groove 510G and the second sub-groove 520G may overlap each other to form the disconnection groove 500G.

In this case, in an embodiment, the refractive layer 520 may include a first tip portion T1 protruding toward the disconnection groove 500G, for example, toward the second sub-groove 520G. The first tip portion T1 may protrude beyond the edge of the light-absorbing layer 510 defining the disconnection groove 500G, for example, the first sub-groove 510G. In other words, the second sub-groove 520G may have a width smaller than width of the first sub-groove 510G such that the first tip portion T1 and the light-absorbing layer 510 may form an undercut structure. In addition, in an embodiment, the refractive layer 520 may include a second tip portion T2 protruding toward the reflective opening 500OP. The second tip portion T2 may protrude beyond the edge of the light-absorbing layer 510 defining therein the reflective opening 500OP such that the second tip portion T1 and the light-absorbing layer 510 may form another undercut structure.

Accordingly, the intermediate layer 220, particularly the common layer CML, on the reflective layer 500 may be disconnected at the disconnection groove 500G.

Referring to FIG. 5, in an embodiment, a plurality of disconnection grooves 500G may be provided. For example, the plurality of disconnection grooves 500G may include a first groove 500G1 and a second groove 500G2. The first groove 500G1 may surround the reflective opening 500OP. The first groove 500G1 may be arranged as a closed loop. The second groove 500G2 may surround the first groove 500G1 and be spaced apart from the first groove 500G1 in a radial direction in a plan view. The second groove 500G2 may be arranged as a closed loop.

In this case, it will be understood that the refractive layer 520 may include tip portions protruding toward the first groove 500G1 and the second groove 500G2, respectively, as described above. For example, the refractive layer 520 may include the first tip portion T1 protruding toward the first groove 500G1 and the second tip portion T2 protruding toward the reflective opening 500OP. In addition, the refractive layer 520 may include a third tip portion T3 facing the first tip portion T1 with respect to the first groove 500G1. In addition, the refractive layer 520 may include a fourth tip portion T4 and a fifth tip portion T5 facing each other with respect to the second groove 500G2.

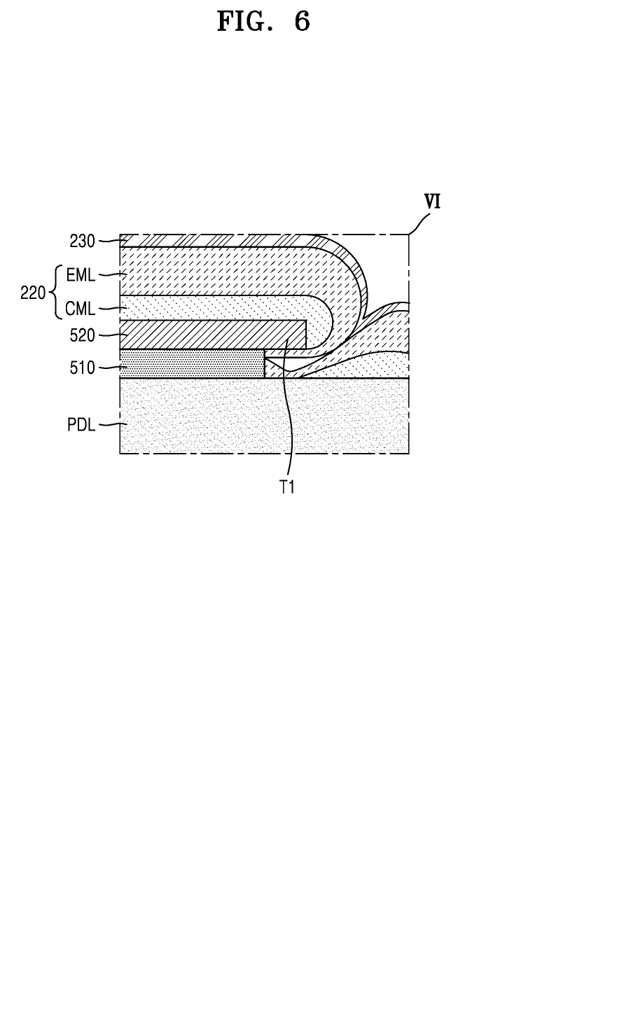

FIG. 6 is a schematic enlarged cross-sectional view of an area VI of the display apparatus of FIG. 4, according to an embodiment.

Referring to FIG. 6, in an embodiment, the intermediate layer 220 may include the common layer CML and the emission layer EML. The common layer CML may be a lower layer of the intermediate layer 220, and the emission layer EML may be an upper layer of the intermediate layer 220 disposed on the common layer CML. In an embodiment, the common layer CML may include the hole injection layer (HIL) and the hole transport layer (HTL), but the disclosure is not necessarily limited thereto. For example, the common layer CML may further include an electron transport layer (ETL) and an electron injection layer (EIL), or the electron transport layer (ETL) and the electron injection layer (EIL) may be disposed on the emission layer EML.

In an embodiment, the intermediate layer 220, for example, the common layer CML, may be disconnected at the first tip portion T1 and the second tip portion T2. That is, the common layer CML may be disconnected at the disconnection groove 500G where the first tip portion T1 is disposed. In addition, the common layer CML may be disconnected at the reflective opening 500OP where the second tip portion T2 is disposed (not shown). In this case, the emission layer EML on the common layer CML may be connected (i.e., monolithic, continuous) without being disconnected at the first tip portion T1 and the second tip portion T2. In addition, the opposite electrode 230 on the emission layer EML may also be connected without being disconnected at the first tip portion T1 and the second tip portion T2. As described above, by disconnecting the common layer CML, lateral leakage of current to an adjacent pixel through the common layer CML may be effectively prevented.

Meanwhile, it will be understood that when the plurality of disconnection grooves 500G are provided, as shown in FIG. 5, the disconnection of the common layer CML may be more reliably ensured, and thus, lateral leakage of current to an adjacent pixel through the common layer CML may be further prevented.

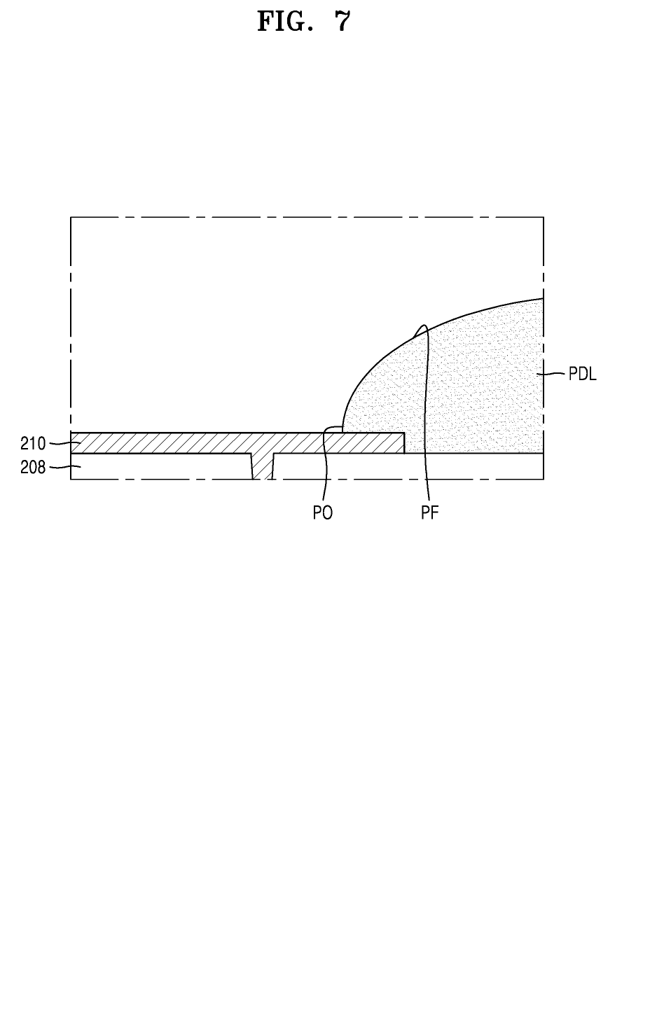

FIGS. 7 to 11 are diagrams schematically showing a method of manufacturing a display apparatus, according to an embodiment. In an embodiment, the method of manufacturing a display apparatus may be used to manufacture the display apparatus described above, but is not necessarily limited thereto.

Referring to FIG. 7, the pixel electrode 210 may be disposed on the planarization layer 208, and the pixel-defining layer PDL may be disposed thereon. The pixel-defining layer PDL may cover the perimeter of the pixel electrode 210 and may define therein the pixel opening PO exposing a central portion of the pixel electrode 210. As described above, the pixel-defining layer PDL may be disposed between the first pixel electrode 211 and the second pixel electrode 212. In addition, the pixel-defining layer PDL may include the inclined surface PF that is downwardly inclined toward each of the first pixel electrode 211 and the second pixel electrode 212. In an embodiment, the inclined surface PF may be convex.

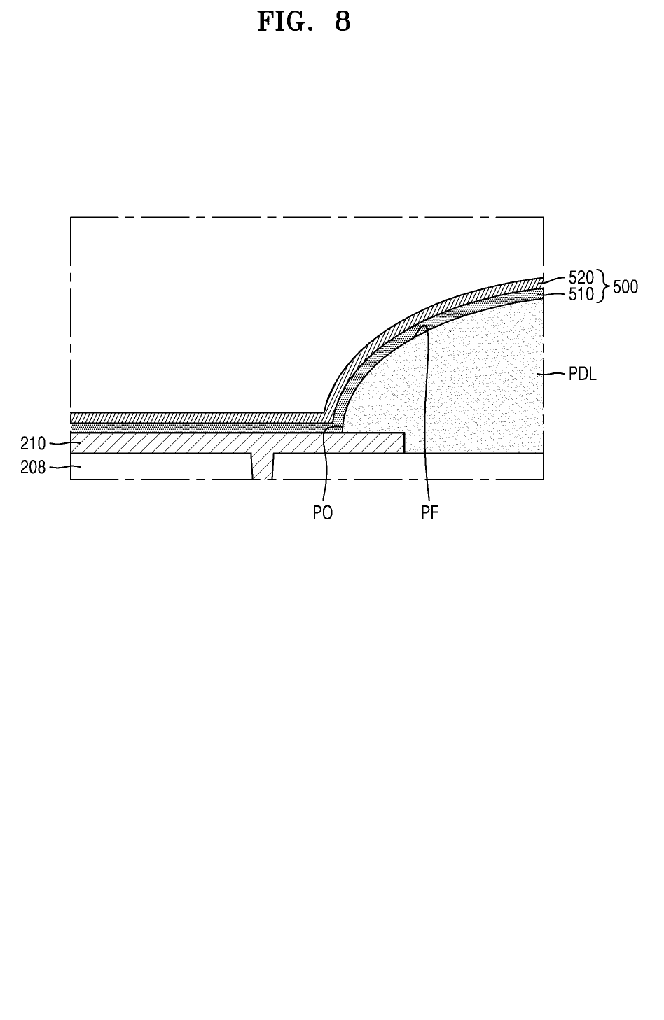

Referring to FIG. 8, the reflective layer 500 may cover the pixel electrode 210 and the pixel-defining layer PDL. As described above, the reflective layer 500 may include the light-absorbing layer 510 and the refractive layer 520. A portion of the reflective layer 500 may be inclined along the inclined surface PF of the pixel-defining layer PDL.

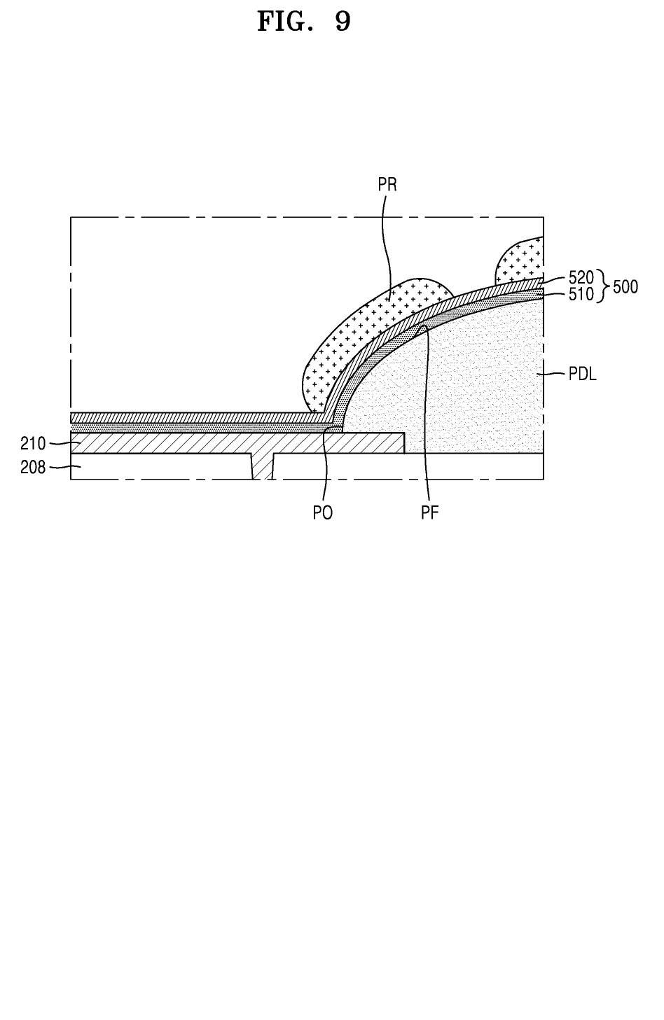

Referring to FIG. 9, a photoresist PR may be disposed on the reflective layer 500. The photoresist PR may be opened to expose a portion of the reflective layer 500. For example, the photoresist PR may be opened in an area overlapping the pixel electrode 210. In addition, the photoresist PR may be opened in an area overlapping a portion of the pixel-defining layer PDL disposed between the first pixel electrode 211 and the second pixel electrode 212, for example, in an area where the disconnection groove 500G is to be formed.

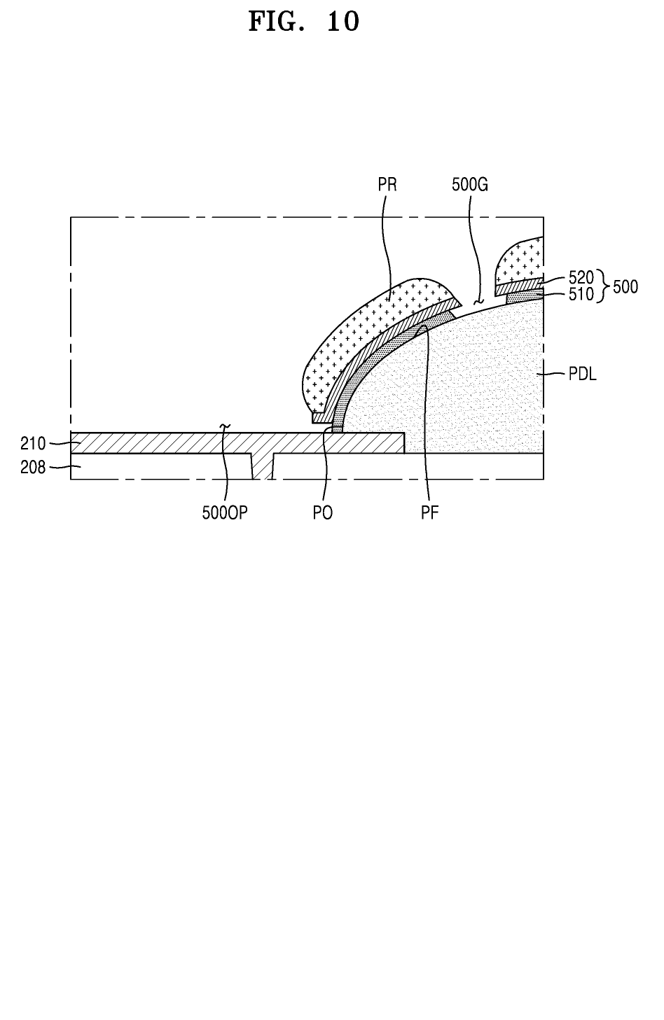

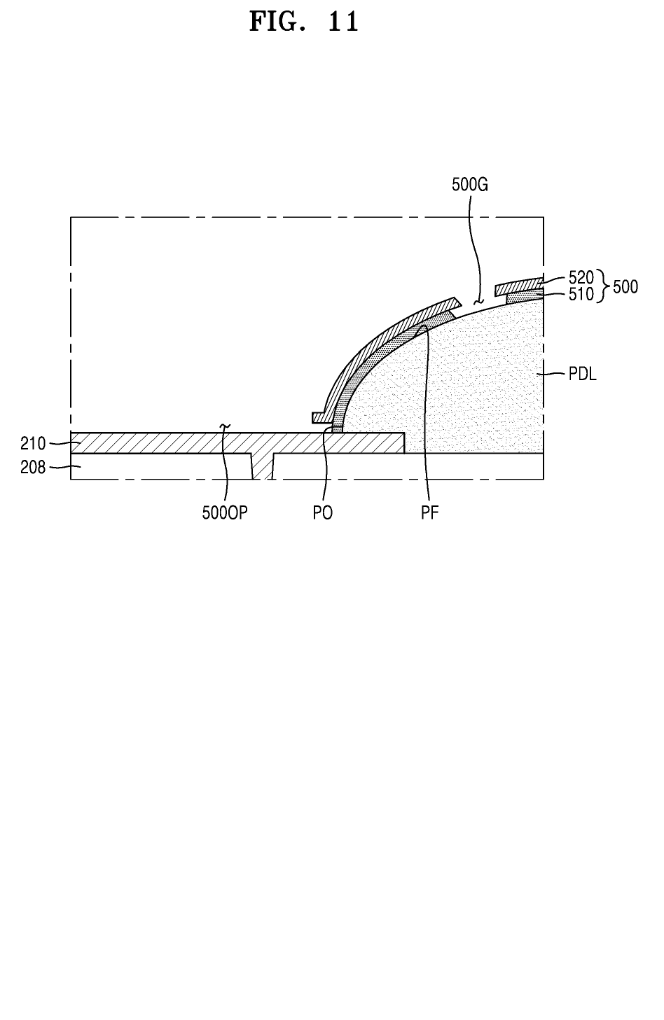

Referring to FIGS. 10 and 11, the reflective layer 500 may be etched using the photoresist PR as a mask. In an embodiment, the reflective layer 500 may be dry-etched. A portion of the reflective layer 500 overlapping the area where the photoresist PR is opened may be removed. Accordingly, the reflective opening 500OP and the disconnection groove 500G may be formed.

Next, in an embodiment, the reflective layer 500 may be wet-etched. In this case, the light-absorbing layer 510 and the refractive layer 520 may include materials having different etch selectivities. Therefore, during wet etching, the light-absorbing layer 510 may be removed more than the refractive layer 520. Accordingly, the refractive layer 520 may form tip portions such as the first tip portion T1 and the second tip portion T2. Next, the photoresist PR may be removed.

According to embodiments, light extraction efficiency may be improved by allowing light emitted from an emission layer to be more effectively emitted to the outside of a display apparatus.

In addition, leakage of light to adjacent pixels may be effectively prevented, and lateral leakage of current to adjacent pixels may be effectively prevented.

The effects of the disclosure are not limited to the effects mentioned above, and other effects not mentioned will be clearly understood by those of ordinary skill in the art from the description of the claims.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a substrate;
a pixel electrode disposed on the substrate and including an emission area;
a pixel-defining layer disposed on the pixel electrode and defining therein a pixel opening exposing the emission area of the pixel electrode;
a reflective layer disposed on the pixel-defining layer and defining therein a reflective opening overlapping the pixel opening in a plan view and exposing the emission area of the pixel electrode; and
an intermediate layer and an opposite electrode, which are disposed on the reflective layer and cover the emission area of the pixel electrode in the pixel opening and the reflective opening,
wherein the reflective layer includes:
a light-absorbing layer disposed on the pixel-defining layer; and
a refractive layer disposed on the light-absorbing layer and being non-metallic.

2. The display apparatus of claim 1, wherein the refractive layer has a refractive index in a range of 4.0 to 5.0.

3. The display apparatus of claim 1, wherein the refractive layer includes amorphous silicon (a-Si).

4. The display apparatus of claim 3, wherein the amorphous silicon is hydrogenated amorphous silicon (a-Si:H).

5. The display apparatus of claim 1, wherein the light-absorbing layer includes a mixture of a molybdenum oxide and a transition metal oxide.

6. The display apparatus of claim 1, wherein
the reflective layer further defines therein a disconnection groove surrounding the reflective opening and spaced apart from a perimeter of the reflective opening in a radial direction in the plan view.

7. The display apparatus of claim 6, wherein the disconnection groove is provided as a closed loop surrounding the reflective opening in the plan view.

8. The display apparatus of claim 6, wherein
the disconnection groove includes a first groove and a second groove, wherein the first groove surrounds the reflective opening, and the second groove surrounds the first groove and is spaced apart from the first groove in the plan view.

9. The display apparatus of claim 6, wherein the refractive layer includes a first tip portion protruding toward the disconnection groove.

10. The display apparatus of claim 9, wherein the first tip portion protrudes beyond an edge of the light-absorbing layer.

11. The display apparatus of claim 9, wherein
the intermediate layer includes a common layer and an emission layer disposed on the common layer, and
the common layer is disconnected by the first tip portion.

12. The display apparatus of claim 9, wherein the refractive layer includes a second tip portion protruding toward the reflective opening.

13. The display apparatus of claim 12, wherein the second tip portion protrudes beyond an edge of the light-absorbing layer.

14. The display apparatus of claim 12, wherein
the intermediate layer includes a common layer and an emission layer disposed on the common layer, and
the common layer is disconnected by the second tip portion.

15. A display apparatus comprising:
a substrate;
a first pixel electrode including a first emission area, and a second pixel electrode including a second emission area, wherein the first pixel electrode and the second pixel electrode are disposed on the substrate;
a pixel-defining layer disposed between and partially on the first pixel electrode and the second pixel electrode and exposing the first emission area and the second emission area; and
a reflective layer disposed on the pixel-defining layer,
wherein the reflective layer includes:
a light-absorbing layer disposed on the pixel-defining layer; and
a refractive layer disposed on the light-absorbing layer and being non-metallic.

16. The display apparatus of claim 15, wherein
the pixel-defining layer includes an inclined surface, which is convex, and
the reflective layer is inclined along the inclined surface.

17. The display apparatus of claim 15, wherein the refractive layer has a refractive index in a range of 4.0 to 5.0.

18. The display apparatus of claim 15, wherein the light-absorbing layer includes a mixture of a molybdenum oxide and a transition metal oxide.

19. The display apparatus of claim 16, wherein
the reflective layer further defines therein a disconnection groove between the first pixel electrode and the second pixel electrode, wherein
the disconnection groove is disposed on the inclined surface.

20. An electronic device comprising:
a display apparatus; and
a housing accommodating the display apparatus,
wherein the display apparatus comprises:
a substrate;
a pixel electrode disposed on the substrate and including an emission area;
a pixel-defining layer disposed on the pixel electrode and defining therein a pixel opening exposing the emission area of the pixel electrode;
a reflective layer disposed on the pixel-defining layer and defining therein a reflective opening overlapping the pixel opening in a plan view and exposing the emission area of the pixel electrode; and
an intermediate layer and an opposite electrode, which are disposed on the reflective layer and cover the emission area of the pixel electrode in the pixel opening and the reflective opening,
wherein the reflective layer includes:
a light-absorbing layer disposed on the pixel-defining layer; and
a refractive layer disposed on the light-absorbing layer and being non-metallic.
